(19) United States
(12) Patent Application Publication
(10) Pub. No.: US 2008/0128832 A1
(43) Pub. Date: Jun. 5, 2008

(54) P-TYPE MOS TRANSISTOR, METHOD OF FORMING THE SAME AND METHOD OF OPTIMIZING THRESHOLD VOLTAGE THEREOF

(75) Inventors: Xiaohui ZHUANG, Shanghai (CN); Shengfen Chiu, Shanghai (CN); Peng Sun, Shanghai (CN)

Correspondence Address: SQUIRE, SANDERS & DEMPSEY L.L.P., 1 MARITIME PLAZA, SUITE 300, SAN FRANCISCO, CA, 94111, US

(73) Assignee: Semiconductor Manufacturing International (Shanghai) Corporation, Shanghai (CN)

(21) Appl. No.: 11/875,828

(22) Filed: Oct. 19, 2007

(30) Foreign Application Priority Data
Dec. 4, 2006 (CN) 200610119060.0

(51) Int. Cl. H01L 29/94; H01L 21/336

(52) U.S. Cl. 257/402; 438/289; 257/E21.409; 257/E29.345

(57) ABSTRACT

The present invention discloses a method of optimizing threshold voltage of P-type MOS transistor, including: providing a semiconductor substrate; forming a P-type MOS transistor on the semiconductor substrate; and performing a second N-type ion implantation in the source and drain extension regions. A P-type MOS transistor and a method for forming the same are also provided, the method includes: providing a semiconductor substrate including a region I and a region II being concentric with the region I and occupying 15% to 25% of the area of the whole semiconductor substrate; forming a P-type MOS transistor on the semiconductor substrate; and performing a second N-type ion implantation in the source and drain extension regions of the region II. Therefore, the reduction in threshold voltage of the P-type MOS transistors in region II of the semiconductor substrate is suppressed.

### FIELD OF THE INVENTION

The present invention relates to the field of semiconductor device, particularly to a P-type MOS transistor, a method of forming the P-type MOS transistor and a method of optimizing the threshold voltage thereof.

### DESCRIPTION OF RELATED ARTS

At present, with the increasing integration of the integrated circuit, the size of device is getting smaller. The feature size of device, which is referred to as the gate length of a MOS transistor, is being scaled down, for example, from 0.13 μm to 0.10 μm. Thus, the gate length of an MOS transistor has a critical impact on the performance of the device. In the prior art, the gate of an MOS transistor is formed by etching the oxide layer, the polysilicon layer, the silicide layer and silicon nitride layer on a semiconductor substrate using plasma. However, the non-uniformity of the etching may result in non-uniform gate lengths of the MOS transistors in different regions on the semiconductor substrate. Particularly, the gate length of an MOS transistor on the edge region of the substrate may be much different from that on the central region of the substrate. Now referring to the figures, FIG. 1 shows a scanning electron microscope (SEM) photograph illustrating the gates of P-type MOS transistors on the central region (i.e., the region I) of a semiconductor substrate in which the white line represents the polysilicon gate. FIG. 2 shows an SEM photograph illustrating the gates of P-type MOS transistors on the edge region (i.e., the region II) of a semiconductor substrate. These two figures are amplified with a same ratio, and each shows the lengths of the polysilicon gates for two adjacent P-type MOS transistors in a same cell. As can be seen from the two figures, the lengths of the polysilicon gates of the P-type MOS transistors on the region I are 172 nm and 153 nm respectively, while the lengths of the polysilicon gates of the corresponding P-type MOS transistors on the region II of the semiconductor substrate are 155 nm and 115 nm respectively. The differences are 17 nm and 28 nm respectively, and the lengths of the polysilicon gates on the region II are shortened by 18.3% compared with those on the region I.

The variation in gate length has a great impact on the threshold voltage of a P-type MOS transistor. FIG. 3 is a diagram showing the distribution of the threshold voltages of P-type MOS transistors fabricated on a semiconductor substrate, in which the numerals represent the threshold voltages (in mV) of P-type MOS transistors fabricated on the substrate. As can be seen, the whole semiconductor substrate is divided into two parts, i.e. an edge region with grey color and a central region with white color. The grey edge region represents the failure portion resulted from an over-low threshold voltage, and the white central region represents the portion that meets the requirement. As can be seen that the threshold voltage values of P-type MOS transistors vary greatly on the whole semiconductor substrate. Comparing to the white central portion, the threshold voltage of a P-type MOS transistor of the grey failure portion drops by a high voltage of 100 mV. Such a reduction in threshold voltage causes a direct current (DC) failure of the MOS transistors on the edge region, and is a great threat to the yield of the products. There is a 30% yield impact by the non-uniformity of threshold voltages in the edge and central portions on the semiconductor substrate.

As has been verified by experiments, the non-uniformity of threshold voltages of P-type MOS transistors are mainly caused by the non-uniformity of plasma during the etch process. FIG. 4 is a schematic diagram of plasma distribution on a semiconductor substrate. As can be seen from FIG. 4, the distribution of plasma is uniform in the region I of the semiconductor substrate, and is not uniform in the region II of the semiconductor substrate, which may result in a lateral etching during the etch process. Thus, the gate of an MOS transistor may be over etched so that the gate length of the MOS transistor may be reduced, thereby decreasing the threshold voltage.

Threshold voltage VT is an important electrical parameter of an MOS transistor, and is also an important parameter in the manufacture processes. The value and uniformity of VT are critical to the performance of a circuit and even to the performance of an integrated system. The US patent No. 20040152247 discloses a method for optimizing threshold voltage of an MOS transistor. In that invention, a first polysilicon layer is formed on a semiconductor substrate firstly, a location of a gate of an MOS transistor is then defined. The first polysilicon layer is etched to a predefined depth. The gate opening is formed in the first polysilicon layer. Then, impurity ions are implanted into the semiconductor substrate through the gate opening. The first polysilicon layer is then removed, and a second polysilicon layer is formed on the semiconductor substrate. Thereby the gate is formed. With this method, the unstable threshold voltage resulted from the heat processing of the source and drain may be prevented. However, the processes are more complicated since the steps of growing polysilicon and photolithography and etching and ion implantation are added. Further, an additional mask is needed, which increases the processing cycle time and the cost.

### SUMMARY OF THE INVENTION

The embodiments of the present invention provide a P-type MOS transistor and a method for forming the same, and a method of optimizing threshold voltage of a P-type MOS transistor, so as to prevent the non-uniformity in threshold voltages of P-type MOS transistors in a central region (i.e. the region I) and an edge region (i.e. the region II) of a semiconductor substrate.

The embodiments of the present invention provide a method of optimizing threshold voltage of a P-type MOS transistor. The method includes providing a semiconductor substrate and forming a P-type MOS transistor on the semiconductor substrate. The step of forming the P-type MOS transistor on the semiconductor substrate includes: forming a gate structure of the P-type MOS transistor, performing a first N-type ion implantation to form source, drain extension regions, performing a P-type ion implantation in the source and drain extension regions to form a source and a drain of the P-type MOS transistor, and performing a second N-type ion implantation in the source and drain extension regions, wherein a threshold voltage of the P-type MOS transistor depends on the dosage of the second N-type ion implantation, the energy of the second N-type ion implantation ranges from 100 to 160 KeV.

The first N-type ions and the second N-type ions both are As ions.

The dosage of the second N-type ion implantation ranges from 0.7E12 to 1.3E12 cm⁻².

The energy of the first N-type ion implantation ranges from 100 to 160 KeV, and the dosage of the first N-type ion implantation ranges from 1.5E13 to 2.5E13 cm⁻².

The embodiments of the present invention also provide a method of forming a P-type MOS transistor. The method includes providing a semiconductor substrate including a region I and a region II which is concentric with the region I and surrounds the region I, the region II occupying 15% to 25% of the area of the whole semiconductor substrate; and forming a P-type MOS transistor on the semiconductor substrate. The step of forming the P-type MOS transistor on the semiconductor substrate includes forming a gate structure of the P-type MOS transistor, performing a first N-type ion implantation to form source, drain extension regions, performing a P-type ion implantation to form a source and a drain of the P-type MOS transistor, and performing a second N-type ion implantation in the source and drain extension regions of the region II, wherein a threshold voltage of the P-type MOS transistor depends on the dosage of the second N-type ion implantation, and the energy of the second N-type ion implantation ranges from 100 to 160 KeV.

The first N-type ions and the second N-type ions both are As ions.

The dosage of the second N-type ion implantation ranges from 0.7E12 to 1.3E12 cm⁻².

The energy of the first N-type ion implantation ranges from 100 to 160 KeV, and the dosage of the first N-type ion implantation ranges from 1.5E13 to 2.5E13 cm⁻².

The embodiments of the present invention also provide a P-type MOS transistor. The P-type MOS transistor includes a semiconductor substrate including a region I and a region II which is concentric with the region I and surrounds the region I, the region II occupying 15% to 25% of the area of the whole semiconductor substrate; and a P-type MOS transistor formed on the semiconductor substrate. The P-type MOS transistor includes a gate structure of the P-type MOS transistor, source and drain extension regions formed by a first N-type ion implantation, a source and a drain of the P-type MOS transistor formed by a P-type ion implantation, and a second N-type ion implantation region in the source and drain extension regions of the region II, wherein a threshold voltage of the P-type MOS transistor depends on the dosage of the second N-type ion implantation.

The ions implanted into the first N-type ion implantation region and the second N-type ion implantation region both are As ions.

The dosage of the second N-type ion implantation ranges from 0.7E12 to 1.3E12 cm⁻².

The implantation energy of the first N-type ion implantation region ranges from 100 to 160 KeV, and the dosage of the first N-type ion implantation ranges from 1.5E13 to 2.5E13 cm⁻².

The present invention has the following advantages over the prior art: the doping concentration of the semiconductor substrate surface is increased by a second ion implantation in the source and drain extension regions of a P-type MOS transistor in a semiconductor substrate, so that the threshold voltage of the P-type MOS transistor is optimized.

In the present invention, by means of the second ion implantation in the source and drain extension regions of a region II (i.e., the edge region) in the semiconductor substrate, the reduction of threshold voltage due to the reduction of gate lengths of P-type MOS transistors in the region II of the semiconductor substrate resulted from the plasma etching is suppressed.

### BRIEF DESCRIPTION OF THE DRAWINGS

FIG. 1 shows a SEM photograph illustrating the gates of P-type MOS transistors on the region I of a semiconductor substrate in the prior art;

FIG. 2 shows a SEM photograph illustrating the gates of P-type MOS transistors on the region II of a semiconductor substrate in the prior art;

FIG. 3 is a diagram showing the distribution of the threshold voltages of P-type MOS transistors formed on a semiconductor substrate in the prior art;

FIG. 4 is a schematic diagram of plasma distribution during plasma etching in the prior art;

FIGS. 5A-5B are schematic diagrams showing a structure of optimizing the threshold voltage of a P-type MOS transistor according to an embodiment of the present invention;

FIGS. 6A-6M are schematic diagrams showing a structure of forming a P-type MOS transistor according to an embodiment of the present invention;

FIG. 7A is a statistical diagram of threshold voltages of P-type MOS transistors formed according to an embodiment of the present invention;

FIG. 7B is a statistical diagram of threshold voltages of P-type MOS transistors formed according to the prior art;

FIG. 8 is a diagram showing the distribution of threshold voltages of P-type MOS transistors formed according to an embodiment of the present invention.

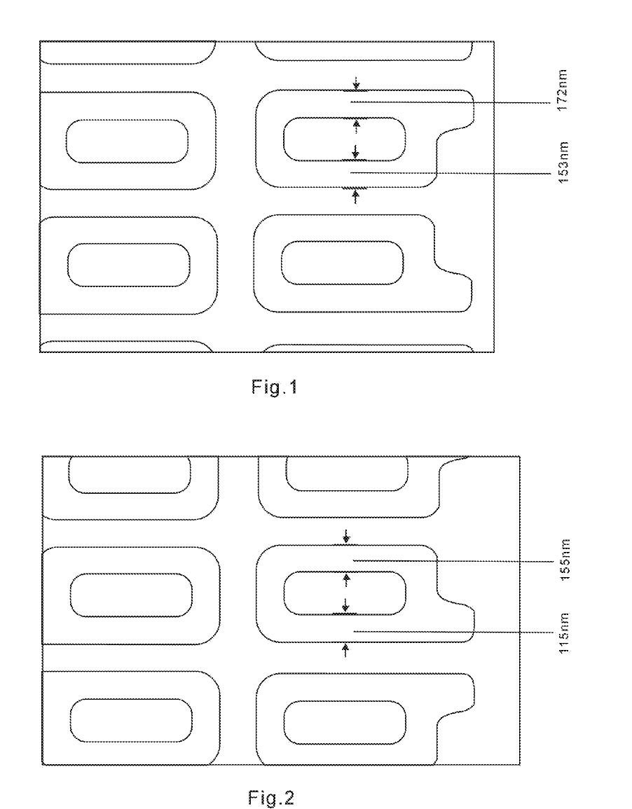

### DETAILED DESCRIPTION OF THE INVENTION

In the present invention, the doping concentration of source and drain extension regions of a semiconductor substrate is changed by means of a second N-type ion implantation, so as to optimize the threshold voltage of a P-type MOS transistor. The second N-type ion implantation may be performed before forming the P-type MOS transistor, or after forming the P-type MOS transistor, or after source, drain implantation during the process of forming the P-type MOS transistor. In the embodiments of the present invention, the second N-type ion implantation is performed after forming the source and drain of the P-type MOS transistor, which should not unduly limit the scope of the present invention. The location of the second N-type ion implantation is at the source and drain extension regions of the P-type MOS transistor. The dosage of the second N-type ion implantation is determined according to the desired threshold voltage and ranges from 0.7E12 to 1.3E12 cm⁻² in the embodiments of the present invention, which should not unduly limit the scope of the present invention. The energy of the second N-type ion implantation ranges from 100 to 160 KeV.

Firstly, the embodiments of the present invention provide a method of optimizing threshold voltage of a P-type MOS transistor. The method includes: providing a semiconductor substrate and forming a P-type MOS transistor on the semiconductor substrate. The step of forming the P-type MOS transistor on the semiconductor substrate includes forming a gate structure of the P-type MOS transistor, performing a first N-type ion implantation to form source, drain extension regions and performing a P-type ion implantation to form a source and a drain of the P-type MOS transistor, and performing a second N-type ion implantation in the source and drain extension. The dosage of the second N-type ion implantation is determined according to a threshold voltage of the P-type MOS transistor, and the energy of the second N-type ion implantation ranges from 100 to 160 KeV.

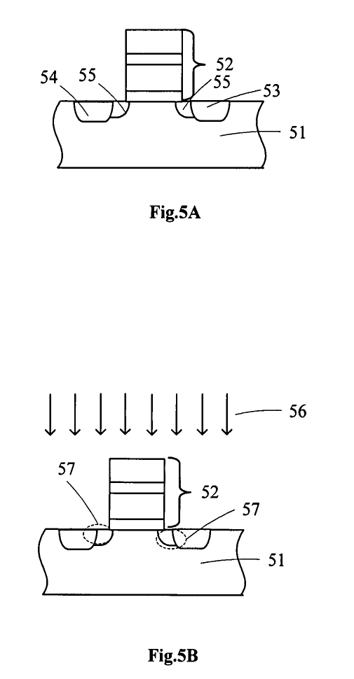

Refer to FIG. 5A, a semiconductor substrate 51 is provided, and a P-type MOS transistor is formed on the semiconductor substrate 51. The step of forming the P-type MOS transistor includes forming a gate structure 52 of the P-type MOS transistor, performing a first N-type ion implantation to form source, drain extension regions 55 and performing a P-type ion implantation to form a source 53 and a drain 54 of the P-type MOS transistor. The gate structure 52 of the P-type MOS transistor includes an oxide layer, a polysilicon layer, a silicide layer and a silicon nitride layer in order from the substrate. The oxide layer is used as a dielectric layer in the gate of the P-type MOS transistor and the polysilicon is used as the gate of the P-type MOS transistor. The silicide layer is to reduce the contact resistance and the silicon nitride layer is to prevent the oxidation of the gate of the P-type MOS transistor.

The ions for the first N-type ion implantation are ions of the group VA, preferably, the arsenic (As) ions. The energy of the first N-type ion implantation ranges from 100 to 160 KeV, and the dosage of the first N-type ion implantation ranges from 1.5E13 to 2.5E13 cm⁻².

Refer to FIG. 5B, a second N-type ion implantation 56 is performed in the source and drain extension regions 55 of the semiconductor substrate 51 to form the second N-type ion implantation region 57. The ions of the second N-type ion implantation 56 are ions of the group VA, preferably, the arsenic (As) ions. The energy of the second N-type ion implantation 56 ranges from 100 to 160 KeV, and the dosage of the second N-type ion implantation 56 ranges from 0.7E12 to 1.3E12 cm⁻².

In an embodiment of the present invention, arsenic ions are implanted into the semiconductor substrate 51, the energy of arsenic ion implantation is 130 keV, and accordingly, the depth implanted into the substrate is 78 nm. The dosage of the implanted arsenic ions is 0.9E12 cm⁻².

The embodiments of the present invention also provide a method of forming a P-type MOS transistor. The method includes: providing a semiconductor substrate including a region I and a region II which is concentric with the region I and surrounds the region I, the region II occupying 15% to 25% of the area of the whole semiconductor substrate; forming a P-type MOS transistor on the semiconductor substrate, the step of forming the P-type MOS transistor includes forming a gate structure of the P-type MOS transistor, performing a first N-type ion implantation to form source, drain extension regions and performing a P-type ion implantation to form a source and a drain of the P-type MOS transistor, and performing a second N-type ion implantation in the source and drain extension regions of the region II. The threshold voltage of the P-type MOS transistor depends on the dosage of the second N-type ion implantation, and the energy of the second N-type ion implantation ranges from 100 to 160 KeV.

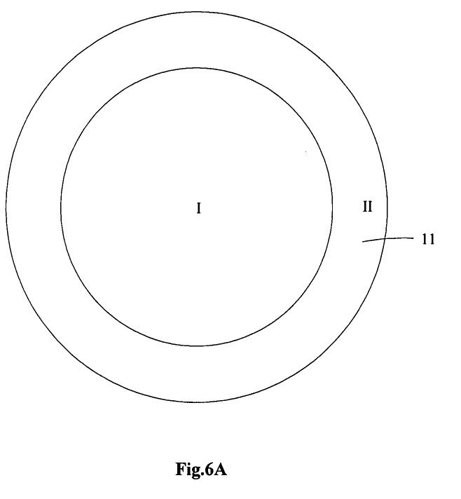

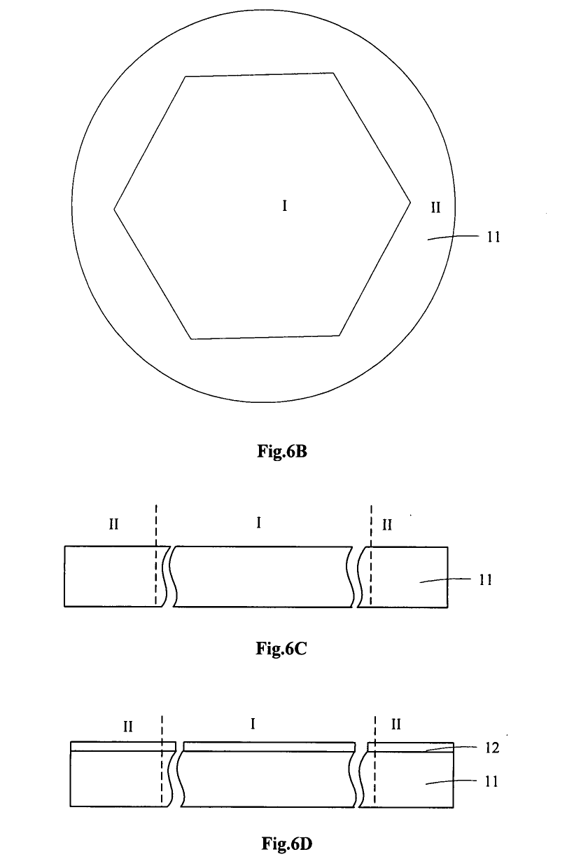

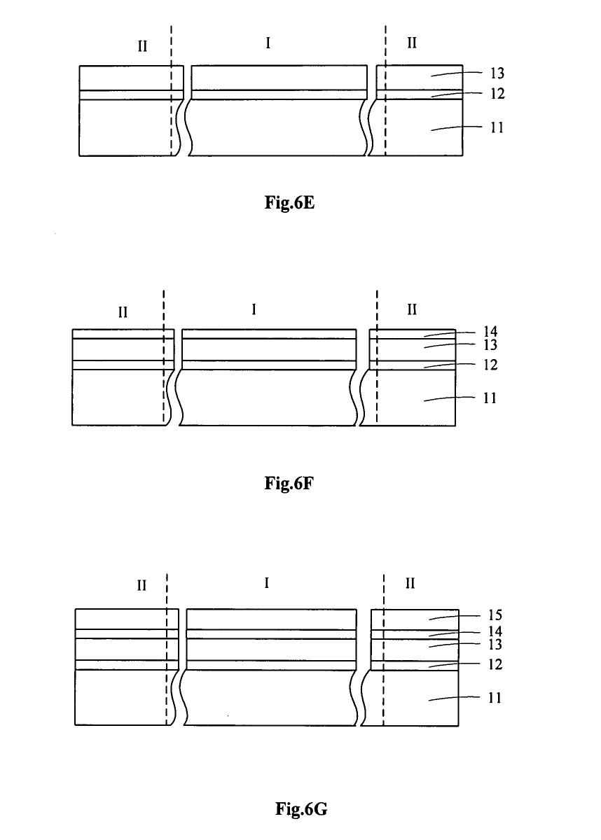

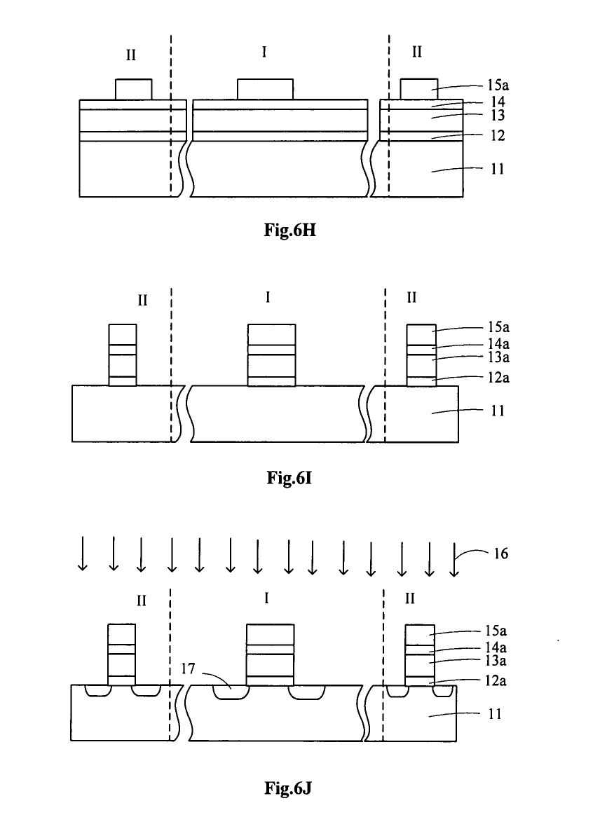

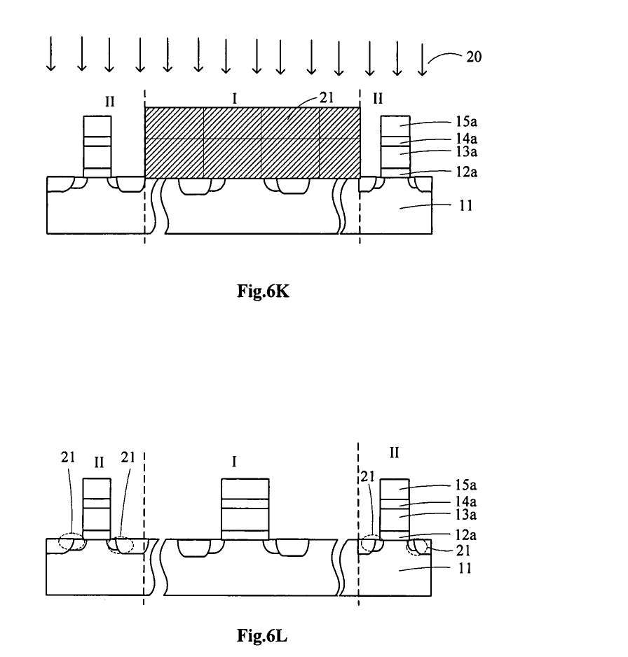

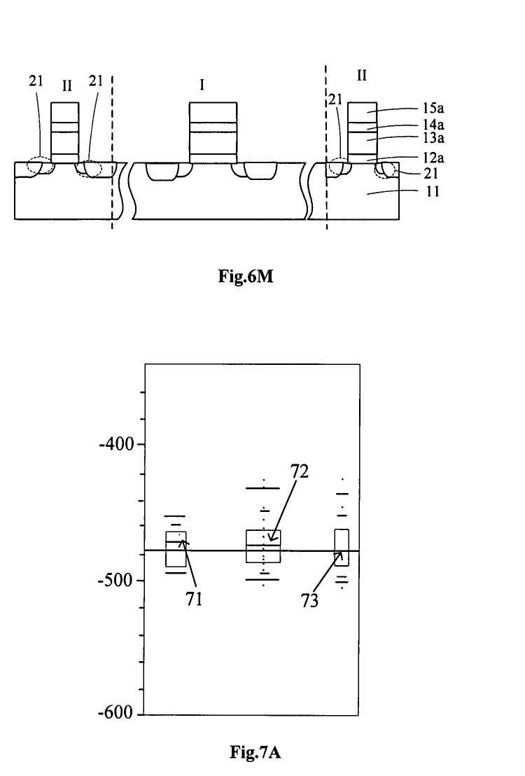

Refer to FIG. 6A, a semiconductor substrate 11 is provided. The semiconductor substrate 11 includes a region I and a region II which is concentric with the region I and surrounds the region I, and the region II occupies 15% to 25% of the area of the whole semiconductor substrate. The region I may be a circle as shown in FIG. 6A, or may be a polygon as shown in FIG. 6B. The region II surrounds the region I. FIG. 6C shows a cross-sectional diagram of a semiconductor substrate, in which the region I and the region II is separated by broken lines.

Ions are implanted into the semiconductor substrate 11 to form an N-well (not shown). The N-well may be formed by multiple implantations. Ions are implanted into the semiconductor substrate 11 to optimize the threshold voltage of the gate (not shown). It is well know that a threshold voltage of a gate can be optimized by forming an N-well and performing an ion implantation.

Then referring to FIG. 6D, an oxide layer 12 is formed over the semiconductor substrate 11. The oxide layer 12 is silicon oxide, and the method for forming the oxide layer 12 is well known to those skilled in the art. In a preferred embodiment of the present invention, the oxide layer 12 is formed by the method of thermal oxidation. The oxide layer 12 has a thickness ranging from 5.3 to 5.7 nm and is used as the gate dielectric layer of the P-type MOS transistor.

Refer to FIG. 6E, a polysilicon layer 13 is formed over the oxide layer 12. The polysilicon layer 13 is used as the gate of the P-type MOS transistor. The method for forming the polysilicon layer 13 is well known to those skilled in the art. The polysilicon layer 13 has a thickness ranging from 75 to 85 nm.

Refer to FIG. 6F, a silicide layer 14 is formed on the polysilicon layer 13. The silicide layer 14 is used to reduce the contact resistance. Preferably, the silicide layer 14 is made of tungsten silicide. The silicide layer 14 has a thickness ranging from 75 to 85 nm. The method for forming the silicide layer 14 is well known to those skilled in the art.

Referring to FIG. 6G, a silicon nitride layer 15 is formed over the silicide layer 14. The silicon nitride layer 15 is used as a protection layer to protect the gate of the P-type MOS transistor from being oxidized. The method for forming the silicon nitride layer 15 is well known to those skilled in the art.

Now referring to FIG. 6H, a gate pattern is defined by the existing photolithographic technique. Then a first etching is performed to the gate by using photoresist as a mask. The silicon nitride layer 15 is etched to form a silicon nitride layer 15a. The method for etching the silicon nitride layer 15 is well known to those skilled in the art. In an embodiment of the present invention, silicon nitride layer 15 is etched by a plasma etch method using such as CF4, CHF3. The non-uniformity of the plasma density, especially in the edge region (i.e., the region II) of the whole semiconductor substrate 11, tends to result in the lateral etching. Thus, the gate length in the region II may be reduced, which may cause a reduction in threshold voltage of a MOS transistor according to the principle of MOS transistor. Then the photoresist is removed.

Refer to FIG. 6I, the silicide layer 14, the polysilicon layer 13 and the oxide layer 12 are continued to be etched by using the silicon nitride 15a as a mask, to form a silicide layer 14a, a polysilicon layer 13a and an oxide layer 12a. The semiconductor substrate outside the gate is exposed after the etching.

Refer to FIG. 6J, a first N-type ion implantation 16 is performed to the semiconductor substrate 11 in order to prevent the breakdown between the source and drain of the P-type MOS transistor. The ions of the first N-type ion implantation are ions of the group VA, preferably, the arsenic (As) ions. The energy of the first N-type ion implantation ranges from 100 to 160 KeV, and accordingly the depth implanted into the substrate ranges from 70 to 86 nm. The dosage of the first N-type ion implantation ranges from 1.5E13 to 2.5E13 cm⁻². The source and drain extension regions 17 are formed after the first N-type ion implantation 16.

In an embodiment of the present invention, arsenic ions are implanted into the semiconductor substrate 51, the energy of arsenic ion implantation is 140 keV, and accordingly, the depth implanted into the substrate is 80 nm. The dosage of the implanted arsenic ions is 1.0E12 cm⁻².

Referring to FIG. 6K, a source and drain implantation is performed, particularly, P-type ions 18 are implanted into the semiconductor substrate 11 in order to form the source and drain 19 of the P-type MOS transistor. The location of implanting the P-type ions 18 is at both sides of the gate of N-type transistor. The P-type ions are of the group IIIA, preferably, the B (boron) ions. The energy of the ion implantation ranges from 15 to 25 KeV, and the dosage of the P-type ion implantation ranges from 2.5E15 to 3.5E15 cm⁻².

After the source and drain implantation, a rapid thermal oxidation annealing is performed to the semiconductor substrate to repair the crystal lattice damage due to the P-type ion implantation, and the ions are activated to form the source and drain 19.

Now referring to FIG. 6L, photoresist 21 is employed to protect the region I of the semiconductor substrate 11. A second N-type ion implantation 20 is performed to implant ions into the source and drain extension regions 17 in the semiconductor substrate 11 so as to form the second N-type ion implantation regions 21. The ions of the second N-type ion implantation 20 are ions of the group VA, preferably, the arsenic (AS) ions. The energy of the second N-type ion implantation ranges from 100 to 160 KeV, and the dosage of the second N-type ion implantation 20 ranges from 0.7E12 to 1.3E12 cm⁻².

In an embodiment of the present invention, arsenic ions are implanted into the region II of the semiconductor substrate 11, the energy of arsenic ion implantation is 150 keV, and accordingly, the depth implanted into the substrate is 82 nm. The dosage of the implanted arsenic ions is 1.2E12 cm⁻².

In the present invention, a second N-type ion implantation is performed to the source and drain extension regions 17 in the semiconductor substrate in order to optimize the threshold voltage of the MOS transistor. A mask and a step of ion implantation process are added. The processes are simplified and the cost is reduced, compared with implanting ions into the semiconductor substrate below the gate for optimizing a threshold voltage in the prior art.

Referring to FIG. 6M, the photoresist 21 in the region I of the semiconductor substrate 11 is removed, so that the P-type MOS transistor is fabricated on the semiconductor substrate 11.

With reference to FIGS. 6A to 6M and the above description for the processes, an embodiment of forming a P-type MOS transistor on a semiconductor substrate is given below, which is as follows:

A semiconductor substrate 11 which includes a region I and a region II is provided, in which the region II is concentric with the region I and surrounds the region I and occupies 15% to 25% of the area of the whole semiconductor substrate.

Ions are implanted into the semiconductor substrate 11 to form an N-well (not shown). The N-well may be formed by multiple implantations. Ions are implanted into the semiconductor substrate 11 to optimize the threshold voltage of the gate (not shown).

Then, an oxide layer 12 is formed on the semiconductor substrate 11. The oxide layer 12 is formed by thermal oxidation. The oxide layer 12 has a thickness of 5.5 nm and is used as the gate dielectric layer of the P-type MOS transistor.

Then, a polysilicon layer 13 is formed on the oxide layer 12. The polysilicon layer 13 is used as the gate of the P-type MOS transistor. The polysilicon layer 13 has a thickness of 80 nm.

A silicide layer is formed on the polysilicon layer 13. The silicide layer 14 has a thickness of 80 nm.

A silicon nitride layer 15 is formed on the silicide layer 14. The silicon nitride layer 15 is used as a protection layer to protect the gate of the P-type MOS transistor from being oxidized.

A gate pattern is defined by use of the existing photolithographic technique. Then the silicon nitride layer 15 is etched to form a silicon nitride layer 15a by using photoresist as a mask. Then the photoresist is removed.

The silicide layer 14, the polysilicon layer 13 and the oxide layer 12 are continued to be etched by using the silicon nitride 15a as a mask, to form a silicide layer 14a, a polysilicon layer 13a and an oxide layer 12a. The semiconductor substrate outside the gate is exposed after the etching.

Then, a first N-type ion implantation is performed, i.e., arsenic ions are implanted into the semiconductor substrate 11. The energy of the ion implantation is 120 KeV, and accordingly the depth implanted into the substrate is 74 nm. The dosage of the implanted arsenic ions is 1.0E12 cm². The source and drain extension regions 17 are formed after the first N-type ion implantation.

Next, source and drain implantation is performed, particularly, B ions are implanted into the semiconductor substrate 11. The energy of the ion implantation is 20 KeV, and the dosage of the implanted B ions is 3.015 cm⁻².

After the source and drain implantation, a rapid thermal oxidation annealing is performed to form the source and drain 19 in the semiconductor substrate 11.

Then, a second N-type ion implantation 20 is performed, and photoresist 21 is employed to protect the region I of the semiconductor substrate 11. Arsenic ions are implanted into the source and drain extension regions 17 in the semiconductor substrate 11. The energy of the ion implantation is 140 KeV, and the dosage of the implanted arsenic ions is 1.1E12 cm⁻².

Finally, the photoresist 21 on the region I of the semiconductor substrate 11 is removed, and the P-type MOS transistor is fabricated on the semiconductor substrate 11.

FIG. 6M shows the result structure of the P-type MOS transistor obtained from the above described processes. The P-type MOS transistor includes: a semiconductor substrate 11 which includes a region I and a region II, in which the region II is concentric with the region I and surrounds the region I and occupies 15% to 25% of the area of the whole semiconductor substrate; and a P-type MOS transistor formed on the semiconductor substrate, the P-type MOS transistor includes a gate structure of the P-type MOS transistor, source and drain extension regions 17 formed by a first N-type ion implantation and source and drain 19 of the P-type MOS transistor formed by a P-type ion implantation, and second N-type ion implantation regions 21 in the source and drain extension regions 17 of the region II. A threshold voltage of the P-type MOS transistor depends on the dosage of the second N-type ion implantation. The implantation energy of the second N-type ion implantation ranges from 100 to 160 KeV.

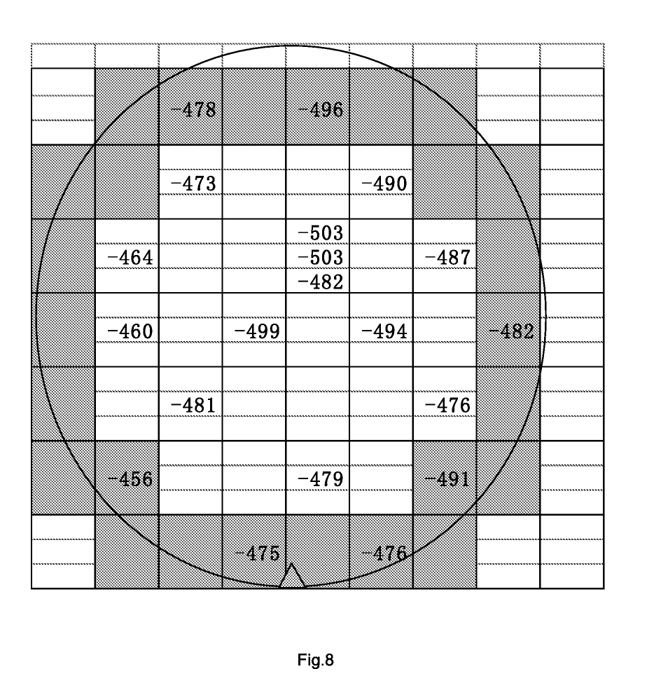

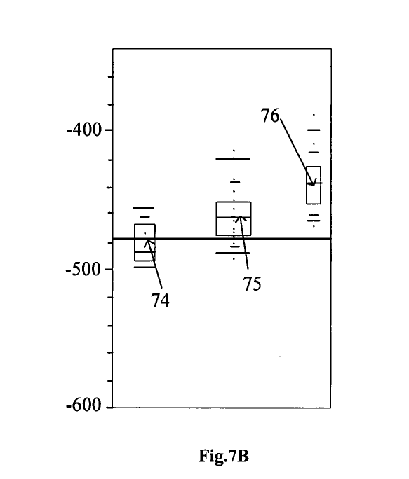

The advanced parameter testing apparatus Type 4072 made by Agilient is employed to test the threshold voltage of the P-type MOS transistor formed by the above processes. The result of the test is as shown in FIG. 7A, while the result of devices fabricated by the prior art is shown in FIG. 7B. As shown in FIG. 7A, reference number 71 represents the threshold voltages of P-type MOS transistors in central part (i.e., the region I) of the semiconductor substrate, reference number 72 represents the threshold voltages of P-type MOS transistors in the region II of the semiconductor substrate, and reference number 73 represents the threshold voltages of P-type MOS transistors in the region II of the semiconductor substrate which is more distant from the central part of the substrate. As can be seen that the mean threshold voltage of P-type MOS transistors in the region II of the semiconductor substrate differs slightly from that in the region I since a second N-type ion implantation is added for the region II of the semiconductor substrate. As shown in FIG. 7B, 74 represents the threshold voltages of P-type MOS transistors in the central of the semiconductor substrate (i.e., the region I), 75 represents the threshold voltages of P-type MOS transistors in the region II of the semiconductor substrate, and 76 represents the threshold voltages of P-type MOS transistors in the region II of the semiconductor substrate which is more distant from the central part of the substrate. As can be seen that the mean threshold voltage of P-type MOS transistors in the region II of the semiconductor substrate has a difference of approximately 50 mV from that in the region I. This shows that the method of the present invention overcomes the problem of non-uniformity in threshold voltage due to the non-uniformity in gate length resulted from the etching processes.

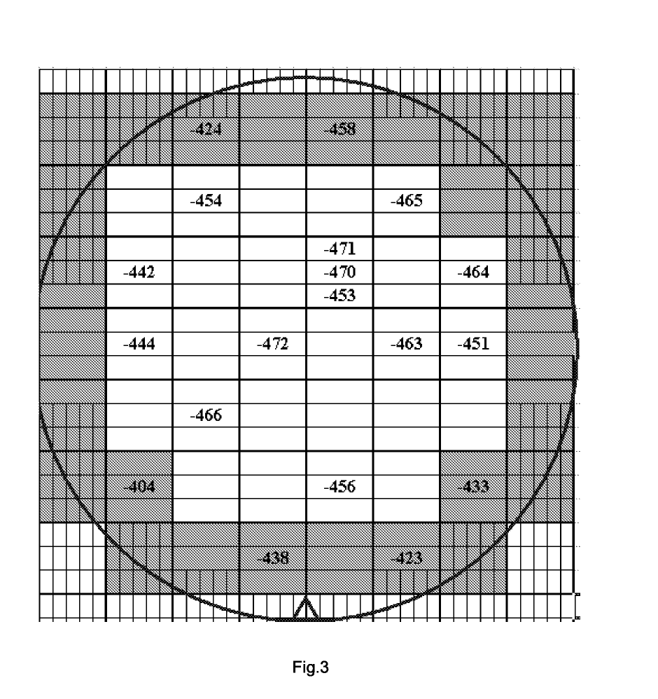

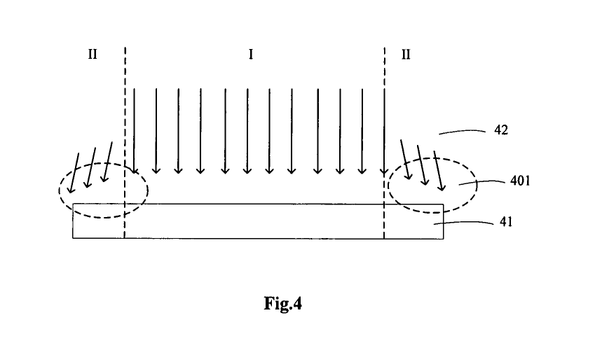

Further, the advanced parameter testing apparatus Type 4072 made by Agilient is employed to test the threshold voltage of the P-type MOS transistor formed by the above processes, and the distribution of the threshold voltage is as shown in FIG. 8. As can be seen, the yield of P-type MOS transistors is improved by 30% to 40%, compared with the prior art shown in FIG. 3.

While the preferred embodiments of the present invention have been described above, the present invention should not be limited to these embodiments. Those skilled in the art would recognize many possible variations, changes and modifications or equivalent embodiments by use of the above teaching, without departing from the scope of the present invention. Therefore, those modifications or changes or equivalent variations without departing from the spirit the substantial content of the present invention are to be included within the protection scope of the present invention.

1. A method of optimizing threshold voltage of a P-type MOS transistor, comprising:
providing a semiconductor substrate;
forming a P-type MOS transistor on the semiconductor substrate, wherein the step of forming the P-type MOS transistor comprises
forming a gate structure of the P-type MOS transistor,
performing a first N-type ion implantation to form a source, drain extension regions, and
performing a P-type ion implantation to form a source and a drain of the P-type MOS transistor; and
performing a second N-type ion implantation in the source and drain extension regions, wherein a threshold voltage of the P-type MOS transistor depends on the dosage of the second N-type ion implantation, and wherein the energy of the second N-type ion implantation ranges from 100 to 160 KeV.

2. The method according to claim 1, wherein the first N-type ions and the second N-type ions both are As ions.

3. The method according to claim 2, wherein the dosage of the second N-type ion implantation ranges from 0.7E12 to 1.3E12 cm−2.

4. The method according to claim 2, wherein the energy of the first N-type ion implantation ranges from 100 to 160 KeV, and wherein the dosage of the first N-type ion implantation ranges from 1.5E13 to 2.5E13 cm⁻².

5. A method of forming a P-type MOS transistor, comprising:
providing a semiconductor substrate including a region I and a region II which is concentric with the region I and surrounds the region I, the region II occupying 15% to 25% of the area of the whole semiconductor substrate;
forming a P-type MOS transistor on the semiconductor substrate, wherein the step of forming the P-type MOS transistor comprises
forming a gate structure of the P-type MOS transistor,
performing a first N-type ion implantation to form source, drain extension regions, and
performing a P-type ion implantation to form a source and a drain of the P-type MOS transistor; and
performing a second N-type ion implantation in the source and drain extension regions of the region II, wherein the dosage of the second N-type ion implantation is determined according to a threshold voltage of the P-type MOS transistor, and wherein the energy of the second N-type ion implantation ranges from 100 to 160 KeV.

6. The method according to claim 5, wherein the first N-type ions and the second N-type ions both are As ions.

7. The method according to claim 6, wherein the dosage of the second N-type ion implantation ranges from 0.7E12 to 1.3E12 cm⁻².

8. The method according to claim 6, wherein the energy of the first N-type ion implantation ranges from 100 to 160 KeV, and wherein the dosage of the first N-type ion implantation ranges from 1.5E13 to 2.5E13 cm⁻².

9. A P-type MOS transistor, comprising:
a semiconductor substrate which includes a region I;
a region II, which is concentric with the region I and surrounds the region I, occupying 15% to 25% of the area of the whole semiconductor substrate; and
a P-type MOS transistor formed on the semiconductor substrate and comprising a gate structure of the P-type MOS transistor, a source and drain extension regions formed by a first N-type ion implantation and a source and a drain of the P-type MOS transistor formed by a P-type ion implantation, wherein the P-type MOS transistor further comprises a second N-type ion implantation region in the source and drain extension regions of the region II, wherein a threshold voltage of the P-type MOS transistor depends on the dosage of the second N-type ion implantation, and wherein the implantation energy of the second N-type ion implantation region ranges from 100 to 160 KeV.

10. The P-type MOS transistor according to claim 9, wherein the ions implanted into the first N-type ion implantation region and the second N-type ion implantation region both are As ions.

11. The P-type MOS transistor according to claim 10, wherein the dosage of the second N-type ion implantation ranges from 0.7E12 to 1.3E12 cm⁻².

12. The P-type MOS transistor according to claim 10, wherein the implantation energy of the first N-type ion implantation region ranges from 100 to 160 KeV, and wherein the dosage of the first N-type ion implantation ranges from 1.5E13 to 2.5E13 cm⁻².
